(19) United States
(12) Patent Application Publication
(10) Pub. No.: US 2013/0098664 A1
(43) Pub. Date: Apr. 25, 2013

(54) Resolution-Adjustable Touch Panel and Manufacturing Method Thereof

(71) Applicants: Yi-Chung Juan, Tainan City (TW); Hsuan-Chen Liu, Kaohsiung City (TW); Sung-Chun Lin, Tainan City (TW); Wen-Chi Lin, New Taipei City (TW)

(72) Inventors: Yi-Chung Juan, Tainan City (TW); Hsuan-Chen Liu, Kaohsiung City (TW); Sung-Chun Lin, Tainan City (TW); Wen-Chi Lin, New Taipei City (TW)

(73) Assignee: HANNSTAR DISPLAY CORP., New Taipei City (TW)

(21) Appl. No.: 13/591,565

(22) Filed: Aug. 22, 2012

(30) Foreign Application Priority Data
Oct. 25, 2011 (TW) 100138986

(51) Int. Cl. H05K 1/14; H05K 13/00

(52) U.S. Cl. 174/254; 29/595

(57) ABSTRACT

A resolution-adjustable touch panel and a manufacturing method thereof. The resolution-adjustable touch panel includes a substrate, a plurality of first, second, third and fourth sensor strings, and a flexible printed circuit. The flexible printed circuit board includes a plurality of first, second, third and fourth pins. The first and third pins are respectively and electrically connected to the first and third sensor strings, and the second and fourth pins are respectively and electrically connected to the second and fourth sensor strings by dummy pins. From this, a different-resolution touch panel can be made from the substrate with the same sensor string. Thus, the cost for masks can be reduced.

### CROSS-REFERENCE TO RELATED APPLICATION

This application claims the benefit of Taiwan Patent Application No. 100138986, filed on Oct. 25, 2011, in the Taiwan Intellectual Property Office, the disclosure of which is incorporated herein by reference.

### FIELD OF THE INVENTION

The present invention relates to a touch panel and a manufacturing method thereof, in particular to a resolution-adjustable touch panel and a manufacturing method thereof.

### BACKGROUND OF THE INVENTION

At present, touch panels have been used extensively in electronic devices to serve as an input device to substitute or supplement a general keyboard or mouse to achieve the effects of controlling and operating the electronic devices to perform various different functions.

A conventional touch panel used for a touch screen usually has sensor strings arranged perpendicularly to each other on the substrate, and then pins of a flexible printed circuit board are provided for receiving touch signals.

However, the touch resolution required by the electronic device varies, and some electronic devices only require less sensor strings, and some electronic devices require more sensor strings to achieve a sensitive touch effect. Therefore, the designer and manufacturers of the touch panel have to use different masks to meet different requirements of various different electronic devices, and thus increasing the manufacturer's cost for masks.

### SUMMARY OF THE INVENTION

In view of the problems of the prior art, it is a primary objective of the present invention to provide a resolution-adjustable touch panel and a manufacturing method thereof to overcome the manufacturer's additional cost for the masks.

To achieve the aforementioned objective, the present invention provides a resolution-adjustable touch panel, comprising: a substrate, a plurality of first sensor strings, a plurality of second sensor strings, a plurality of third sensor strings, a plurality of fourth sensor strings and a flexible printed circuit board. Wherein, the first sensor string and the second sensor string are extended along a first direction and formed on the substrate, and each first sensor string is disposed adjacent to each corresponding second sensor string. The third sensor string and the fourth sensor string are extended in a second direction and formed on the substrate, and each third sensor string is disposed on each corresponding fourth sensor string. More specifically, the first sensor string and the second sensor string are arranged with an interval apart from each other, and the third sensor string and the fourth sensor string are arranged with an interval apart from each other. In addition, the flexible printed circuit board is attached onto a side of substrate, and the flexible printed circuit board comprises a plurality of first pins, a plurality of second pins, a plurality of third pins and a plurality of fourth pins, wherein the first pins and third pins are respectively and electrically connected to the first sensor strings and the third sensor strings, and ends of the second pin and the fourth pin are in form of dummy pins electrically connected to the second sensor string and fourth sensor string.

In other words, the resolution-adjustable touch panel can reduce the resolution of the touch panel by using the dummy pins of the flexible printed circuit board. Wherein, the dummy pins are grounded, floating, or provided with a specific potential to achieve the effect of adjusting a touch resolution.

In addition, the present invention further provides a resolution-adjustable touch panel, comprising: a substrate, a plurality of first sensor strings, a plurality of second sensor strings, a plurality of third sensor strings, a plurality of fourth sensor strings and a flexible printed circuit board. Wherein, the first sensor string and the second sensor string are extended in a first direction and formed on the substrate, and each first sensor string is disposed adjacent to each corresponding second sensor string. The third sensor string and the fourth sensor string are extended along the second direction and formed on the substrate, and each third sensor string is disposed adjacent to each fourth sensor string. More specifically, the first sensor string and the second sensor string are arranged with an interval apart from each other, and the third sensor string and the fourth sensor string are arranged with an interval apart from each other. In addition, the flexible printed circuit board is attached on a side of the substrate, and the flexible printed circuit board comprises a plurality of first pins and a plurality of second pins, wherein each first pin is electrically connected to each first sensor string and each second sensor string at the same time, and each second pin is electrically connected to each third sensor string and each fourth sensor string at the same time to change the resolution of the touch panel.

In addition, the present invention further provides a manufacturing method of a resolution-adjustable touch panel, comprising the steps of: providing a substrate; providing a plurality of first sensor strings, a plurality of second sensor strings, a plurality of third sensor strings and a plurality of fourth sensor strings, and the first sensor strings and the second sensor strings being extended along a first direction and formed on the substrate, and the third sensor strings and the fourth sensor strings being extended along a second direction and formed on the substrate, and each of the first sensor strings being disposed adjacent to each of the corresponding second sensor strings, and each of the third sensor strings being disposed adjacent to each of the corresponding fourth sensor strings; and providing a flexible printed circuit board, attached to a side of the substrate, and the flexible printed circuit board comprising a plurality of first pins, a plurality of second pins, a plurality of third pins and a plurality of fourth pins, and the first pins and the third pins being respectively and electrically connected to the first sensor strings and the third sensor strings, and ends of the second pins and the fourth pins in form of dummy pins being respectively and electrically connected to the second sensor strings and the fourth sensor strings.

In other words, the manufacturing method of the resolution-adjustable touch panel in accordance with the present invention can reduce the resolution of the touch panel by using the dummy pins on the flexible printed circuit board. Wherein, the dummy pins are grounded, floating or provided with a specific potential to achieve the effect of changing the touch resolution.

In addition, the present invention further provides a manufacturing method of a resolution-adjustable touch panel, and the method comprises the steps of: providing a substrate; providing a plurality of first sensor strings extended along a first direction and formed on the substrate; providing a plurality of second sensor strings extended along a second direction and formed on the substrate, and each of the first sensor strings being disposed adjacent to each of the adjacent second sensor strings; providing a plurality of third sensor strings extended along a second direction and formed on the substrate, providing a plurality of fourth sensor strings extended along a second direction and formed on the substrate, and each of the third sensor strings being disposed adjacent to each of the corresponding fourth sensor strings; and providing a flexible printed circuit board, attached to a side of the substrate, and the flexible printed circuit board comprising a plurality of first pins and a plurality of second pins, and each of the first pins being electrically connected to each of the first sensor strings and each of the second sensor strings at the same time, and each of the second pins being electrically connected to each of the third sensor strings and each of the fourth sensor strings at the same time to adjust a touch resolution of the touch panel.

In summation, the resolution-adjustable touch panel and a manufacturing method thereof in accordance with the present invention have the following advantage:

The resolution-adjustable touch panel of the present invention can adjust the resolution of the touch panel by changing the pins of the flexible printed circuit board, so that the cost for the masks can be reduced when the sensor strings are formed on the substrate.

The technical characteristics and effects of the present invention will become apparent with the detailed description of the following preferred embodiments accompanied with the illustration of related drawings as follows.

### BRIEF DESCRIPTION OF THE DRAWINGS

FIG. 1 is a schematic view of a resolution-adjustable touch panel in accordance with a first preferred embodiment of the present invention;

FIG. 2 is a schematic view of a resolution-adjustable touch panel in accordance with a second preferred embodiment of the present invention;

FIG. 3 is a flow chart of a manufacturing method of a resolution-adjustable touch panel in accordance with the present invention; and

FIG. 4 is another flow chart of a manufacturing method of a resolution-adjustable touch panel in accordance with the present invention.

### DESCRIPTION OF THE PREFERRED EMBODIMENTS

The resolution-adjustable touch panel and a manufacturing method thereof in accordance with the present invention are illustrated by the following preferred embodiments, and the same numerals used in the preferred embodiment represent same respective elements.

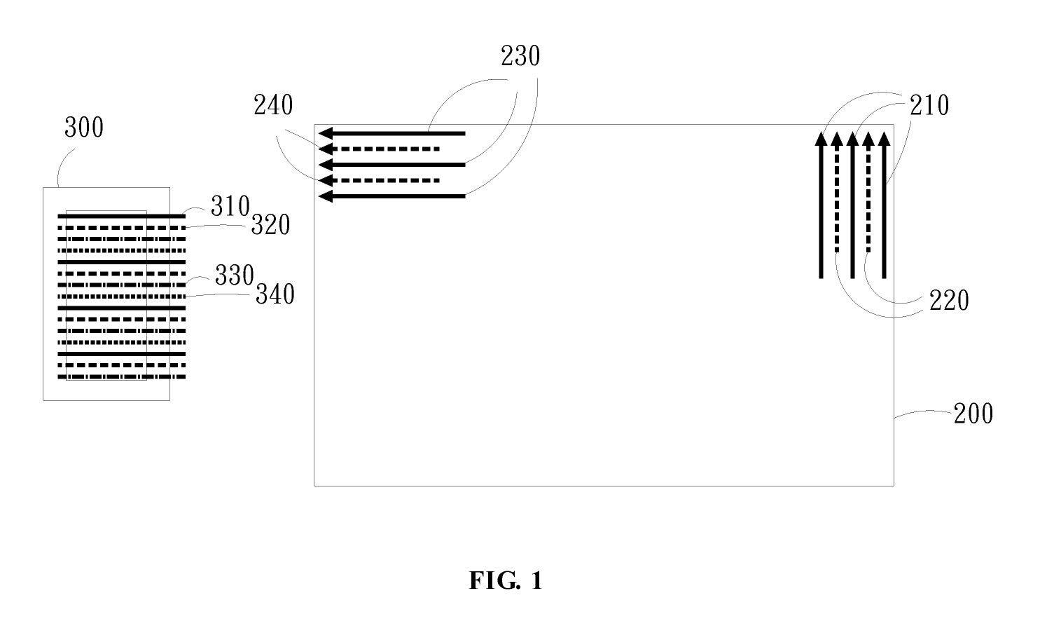

With reference to FIG. 1 for a schematic view of a resolution-adjustable touch panel in accordance with the first preferred embodiment of the present invention, the pins of the flexible printed circuit board and the relation of electrically connecting sensor strings on a substrate are not shown in the figure to simplify the illustration of the invention, and the flexible printed circuit board is not attached onto a side of the substrate to facilitate numbering the components in the drawing, and only a portion of the sensor strings on the substrate are drawn. Although some portions are not drawn, yet the persons ordinarily skilled in the art should be able to understand from the disclosure of the present invention about the relation of electrically connecting the pins of the flexible printed circuit board to the sensor strings on the substrate, and the flexible printed circuit board is attached to a side of the substrate, and the sensor strings on the substrate can be distributed on the whole or a part of the substrate. In FIG. 1, the resolution-adjustable touch panel of the present invention comprises a substrate 200, a plurality of first sensor strings 210, a plurality of second sensor strings 220, a plurality of third sensor strings 230, a plurality of fourth sensor strings 240 and a flexible printed circuit board 300. The first sensor string 210 and the second sensor string 220 are distributed in a first direction on the substrate 200, and the third sensor string 230 and the fourth sensor string 240 are distributed in a second direction on the substrate 200, wherein each first sensor string 210 is disposed adjacent to each corresponding second sensor string 220, and each third sensor string 230 is disposed adjacent to each corresponding second sensor string 240, and the first direction and the second direction are perpendicular to each other, or form an angle with respect to each other. Further, the first sensor strings 210 and the second sensor strings 220 are arranged alternately, and the third sensor strings 230 and the fourth sensor strings 240 are arranged alternately. In addition, the alternate arrangement of the first sensor string 210 and the second sensor string 220 allows several first sensor strings 210 to be arranged between two second sensor strings 220 or several second sensor strings 220 to be arranged between two first sensor strings 210. Similarly, the alternate arrangement of the third sensor strings 230 and the fourth sensor strings 240 allows several third sensor strings 230 to be arranged between two fourth sensor strings 240 or several fourth sensor strings 240 to be arranged between two third sensor strings 230.

In addition, the flexible printed circuit board 300 is attached to a side of the substrate 200, and the flexible printed circuit board 300 comprises a plurality of first pins 310, a plurality of second pins 320, a plurality of third pins 330 and a plurality of fourth pins 340, wherein the first pins 310 and the third pins 330 are respectively and electrically connected to first sensor string 210 and the third sensor string 230, and ends of the second pin 320 and the fourth pin 340 are in form of dummy pins electrically connected to the second sensor string 220 and the fourth sensor string 240. Wherein, the dummy pins can be connected in different ways. For example, the other ends of the second pin 320 and the fourth pin 340 are grounded, floating or provided with a specific potential. Therefore, when a user touches a position of the second sensor string 220 or the fourth sensor string 240, the flexible printed circuit board 300 will be unable to obtain the signal generated by the user's touch, and the user's touched position can be obtained from the first sensor string 210 or the third sensor string 230, and thus the resolution of the touch panel can be changed. The following example is provided to further explain the reason for changing the touch resolution. Assumed that the user's touch position is close to the position of the second sensor string 220 or the fourth sensor string 240, a general touch panel does not adopt the form of dummy pins, so that we can know that the user's touch position is near the position of the second sensor string 220 or the fourth sensor string 240. However, the second sensor string 220 or the fourth sensor string 240 adopts the form of dummy pins electrically connected to the second pin 320 and the fourth pin 340 in the resolution-adjustable touch panel of the present invention, so that although the user's touch position is close to the position of the second sensor string 220 or the fourth sensor string 240, the resolution-adjustable touch panel of the present invention can determine whether the user's touch position is situated at a position of the first sensor string 210 or the third sensor string 230 near the second sensor string 220 or the fourth sensor string 240 through a position of a detected signal of the first sensor string 210 or the third sensor string 230 near the second sensor string 220 or the fourth sensor string 240. Overall speaking, the resolution of the touch panel has changed. In other words, the resolution-adjustable touch panel of the present invention adopts the dummy pins in the flexible printed circuit board 300, so that a substrate 200 with the same sensor strings can provide different touch resolutions.

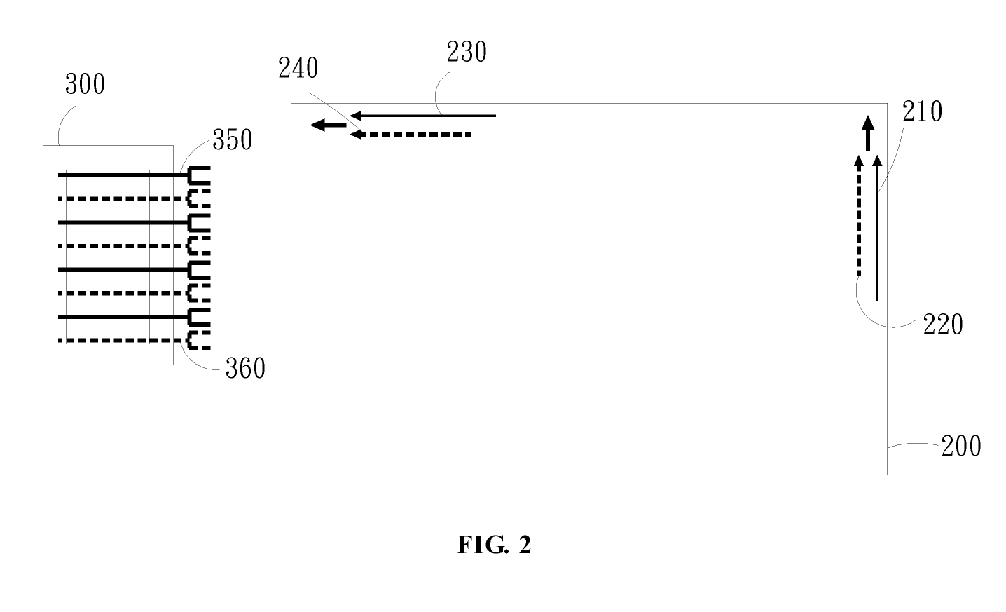

In addition, the present invention further provides another resolution-adjustable touch panel. With reference to FIG. 2 for a schematic view of a resolution-adjustable touch panel in accordance with the second preferred embodiment of the present invention, the pins of the flexible printed circuit board and the relation of electrically connecting sensor strings on a substrate are not shown in the figure to simplify the illustration of the invention, and the flexible printed circuit board is not attached onto a side of the substrate to facilitate numbering the components in the drawing, and only a portion of the sensor strings on the substrate are drawn. Although some portions are not drawn, yet the persons ordinarily skilled in the art should be able to understand from the disclosure of the present invention about the relation of electrically connecting the pins of the flexible printed circuit board to the sensor strings on the substrate, and the flexible printed circuit board is attached to a side of the substrate, and the sensor strings on the substrate can be distributed on the whole or a part of the substrate. In FIG. 2, the resolution-adjustable touch panel of the present invention comprises a substrate 200, a plurality of first sensor strings 210, a plurality of second sensor strings 220, a plurality of third sensor strings 230, a plurality of fourth sensor strings 240 and a flexible printed circuit board 300. The difference between the second preferred embodiment and the first preferred embodiment resides on that the flexible printed circuit board 300 of the second preferred embodiment comprises a plurality of first pins 350 and a plurality of second pins 360, wherein each first pin 350 is electrically connected to each first sensor string 210 and each second sensor string 220, and each second pin 360 is electrically connected to each third sensor string 230 and each fourth sensor string 240. More specifically, the second preferred embodiment mainly electrically connects the adjacent sensor strings by the same pin of the flexible printed circuit board 300. Adjacent first sensor string 210 and second sensor string 220 are used as an example. Regardless of the user's touch position at the first sensor string 210 or the second sensor string 220, the first pin 350 of the flexible printed circuit board 300 will receive the same signal, so that the touch resolution of the substrate 200 can be changed. It is noteworthy to point out that the first pin 350 can be electrically connected to one or more first sensor strings 210 and second sensor strings 220 according to the required resolution. Similarly, the second pin 360 can be electrically connected to one or more third sensor strings 230 and fourth sensor strings 240.

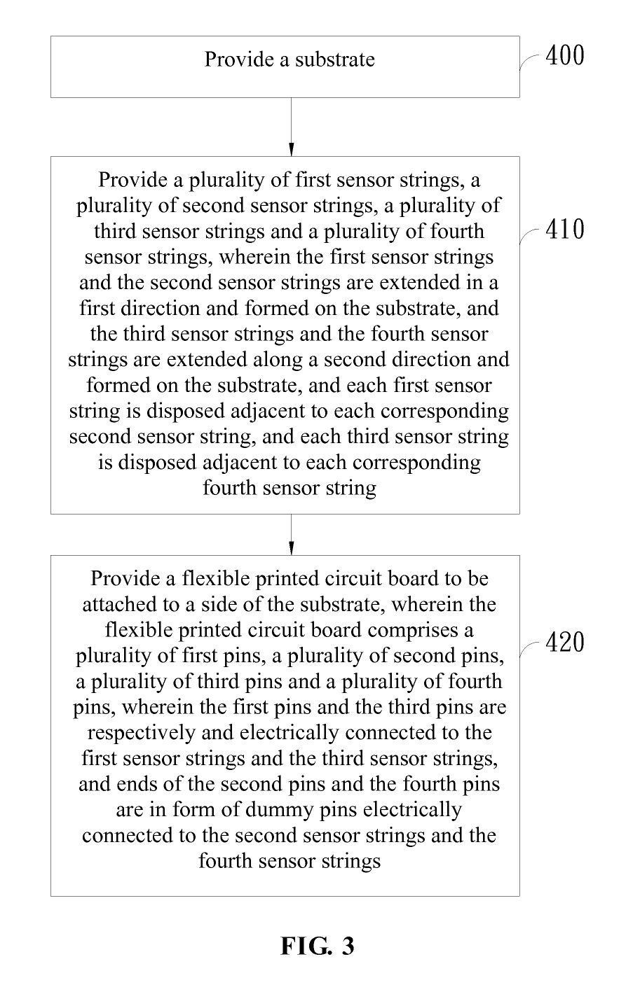

With reference to FIG. 3 for a flow chart of a manufacturing method of a resolution-adjustable touch panel in accordance with the present invention, the manufacturing method comprises the following steps:

Step 400: Provide a substrate.

Step 410: Provide a plurality of first sensor strings, a plurality of second sensor strings, a plurality of third sensor strings and a plurality of fourth sensor strings, wherein the first sensor strings and the second sensor strings are extended in a first direction and formed on the substrate, and the third sensor strings and the fourth sensor strings are extended along a second direction and formed on the substrate, and each first sensor string is disposed adjacent to each corresponding second sensor string, and each third sensor string is disposed adjacent to each corresponding fourth sensor string.

Step 420: Provide a flexible printed circuit board to be attached to a side of the substrate, wherein the flexible printed circuit board comprises a plurality of first pins, a plurality of second pins, a plurality of third pins and a plurality of fourth pins, wherein the first pins and the third pins are respectively and electrically connected to the first sensor strings and the third sensor strings, and ends of the second pins and the fourth pins are in form of dummy pins electrically connected to the second sensor strings and the fourth sensor strings, wherein the dummy pins can be grounded, floating or provided with a specific potential. It is noteworthy to point out that the operation principle and effect have been described in the foregoing preferred embodiment, and thus will not be described again.

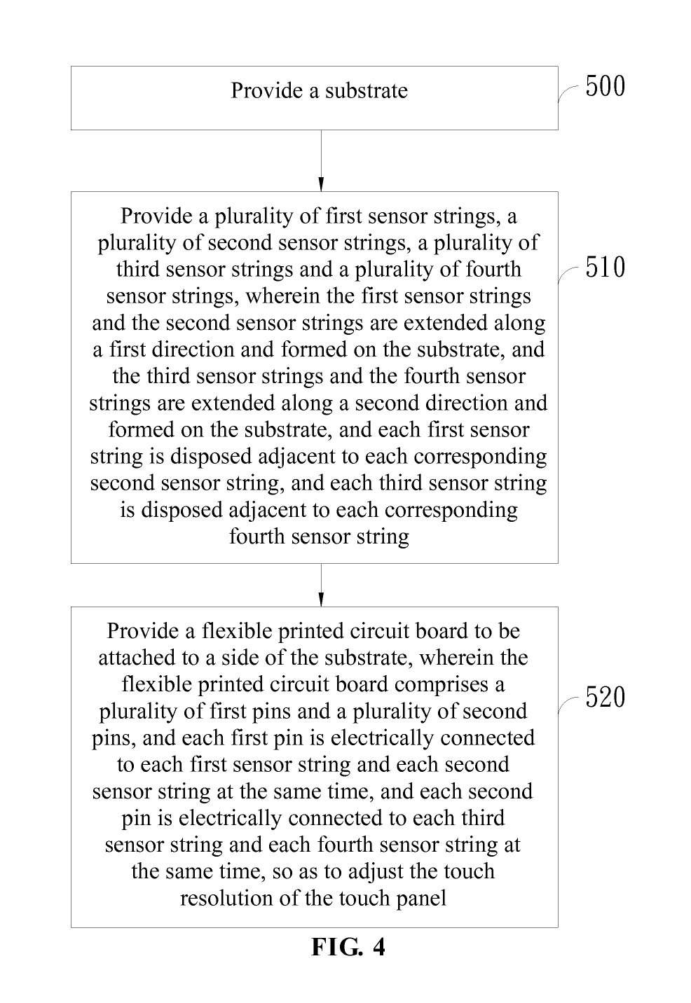

With reference to FIG. 4 for another flow chart of a manufacturing method of a resolution-adjustable touch panel in accordance with the present invention, the manufacturing method comprises the following steps:

Step 500: Provide a substrate.

Step 510: Provide a plurality of first sensor strings, a plurality of second sensor strings, a plurality of third sensor strings and a plurality of fourth sensor strings, wherein the first sensor strings and the second sensor strings are extended along a first direction and formed on the substrate, and the third sensor strings and the fourth sensor strings are extended along a second direction and formed on the substrate, and each first sensor string is disposed adjacent to each corresponding second sensor string, and each third sensor string is disposed adjacent to each corresponding fourth sensor string.

Step 520: Provide a flexible printed circuit board to be attached to a side of the substrate, wherein the flexible printed circuit board comprises a plurality of first pins and a plurality of second pins, and each first pin is electrically connected to each first sensor string and each second sensor string at the same time, and each second pin is electrically connected to each third sensor string and each fourth sensor string at the same time. It is noteworthy to point out that the operation principle and effect have been described in the foregoing preferred embodiment, and thus will not be described again.

The resolution-adjustable touch panel and the manufacturing method thereof in accordance with the present invention have the following advantage. To change the resolution of the touch panel for various different electronic products, the pins of the flexible printed circuit board and the sensor strings of the substrate can be electrically connected in different ways to achieve the effect of adjusting the resolution of the touch panel. Therefore, a substrate with the same sensor strings can provide different resolutions of a touch panel, so as to reduce the cost for masks.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A resolution-adjustable touch panel, comprising:
a substrate;
a plurality of first sensor strings, extended along a first direction and formed on the substrate;
a plurality of second sensor strings, extended along the first direction and formed on the substrate, and each of the first sensor strings being disposed adjacent to each of the corresponding second sensor strings;
a plurality of third sensor strings, extended along a second direction and formed on the substrate;
a plurality of fourth sensor strings, extended along the second direction and formed on the substrate, and each of the third sensor strings being disposed adjacent to each of the corresponding fourth sensor strings; and
a flexible printed circuit board, attached onto a side of the substrate, and comprising a plurality of first pins, a plurality of second pins, a plurality of third pins and a plurality of fourth pins, wherein the first pins and the third pins are respectively and electrically connected to the first sensor strings and the third sensor strings, and ends of the second pins and the fourth pins in form of dummy pins are electrically connected to the second sensor strings and the fourth sensor strings.

2. The resolution-adjustable touch panel of claim 1, wherein other ends of the second pins and the fourth pins are grounded.

3. The resolution-adjustable touch panel of claim 1, wherein the second pins and the fourth pins are floating.

4. The resolution-adjustable touch panel of claim 1, wherein the second pins and the fourth pins come with a specific potential.

5. A resolution-adjustable touch panel, comprising:
a substrate;
a plurality of first sensor strings, extended in a first direction and formed on the substrate;
a plurality of second sensor strings, extended in a first direction and formed on the substrate, and each of the first sensor strings being disposed adjacent to each of the corresponding second sensor strings;
a plurality of third sensor strings, extended in a second direction and formed on the substrate;
a plurality of fourth sensor strings, extended in a second direction and formed on the substrate, and each of the third sensor strings being disposed adjacent to each of the corresponding fourth sensor strings; and
a flexible printed circuit board, attached onto a side of the substrate, and comprising a plurality of first pins and a plurality of second pins, wherein each of the first pins is electrically connected to each of the first sensor strings and each of the second sensor strings at the same time, and each of the second pins is electrically connected to each of the third sensor strings and each of the fourth sensor strings at the same time to adjust a touch resolution of the touch panel.

6. A manufacturing method of a resolution-adjustable touch panel, comprising the steps of:
providing a substrate;
providing a plurality of first sensor strings, a plurality of second sensor strings, a plurality of third sensor strings and a plurality of fourth sensor strings, and the first sensor strings and the second sensor strings being extended along a first direction and formed on the substrate, and the third sensor strings and the fourth sensor strings being extended along a second direction and formed on the substrate, and each of the first sensor strings being disposed adjacent to each of the corresponding second sensor strings, and each of the third sensor strings being disposed adjacent to each of the corresponding fourth sensor strings; and
providing a flexible printed circuit board, attached to a side of the substrate, and the flexible printed circuit board comprising a plurality of first pins, a plurality of second pins, a plurality of third pins and a plurality of fourth pins, and the first pins and the third pins being respectively and electrically connected to the first sensor strings and the third sensor strings, and ends of the second pins and the fourth pins in form of dummy pins being respectively and electrically connected to the second sensor strings and the fourth sensor strings.

7. The manufacturing method of a resolution-adjustable touch panel as recited in claim 6, wherein other ends of the second pins and the fourth pins are grounded.

8. The manufacturing method of a resolution-adjustable touch panel as recited in claim 6, wherein the second pins and the fourth pins are floating.

9. The manufacturing method of a resolution-adjustable touch panel as recited in claim 6, wherein the second pins and the fourth pins come with a specific potential.

10. A manufacturing method of a resolution-adjustable touch panel, comprising the steps of:
providing a substrate;
providing a plurality of first sensor strings extended along a first direction and formed on the substrate;
providing a plurality of second sensor strings extended along a second direction and formed on the substrate, and each of the first sensor strings being disposed adjacent to each of the adjacent second sensor strings;
providing a plurality of third sensor strings extended along a second direction and formed on the substrate,
providing a plurality of fourth sensor strings extended along a second direction and formed on the substrate, and each of the third sensor strings being disposed adjacent to each of the corresponding fourth sensor strings; and
providing a flexible printed circuit board, attached to a side of the substrate, and the flexible printed circuit board comprising a plurality of first pins and a plurality of second pins, and each of the first pins being electrically connected to each of the first sensor strings and each of the second sensor strings at the same time, and each of the second pins being electrically connected to each of the third sensor strings and each of the fourth sensor strings at the same time to adjust a touch resolution of the touch panel.
